(19) United States
(12) Patent Application Publication
(10) Pub. No.: US 2026/0223391 A1
(43) Pub. Date: Jul. 30, 2026

(54) SEMICONDUCTOR DEVICE AND METHOD FOR FABRICATING THE SAME

(71) Applicant: Hon Young Semiconductor Corporation, Hsinchu City (TW)

(72) Inventor: Yu-Lien CHIU, Hsinchu City (TW)

(21) Appl. No.: 19/079,401

(22) Filed: Mar. 13, 2025

(30) Foreign Application Priority Data
Jan. 24, 2025 (TW) 114103641

(51) Int. Cl. H10D 30/66; H10D 30/01; H10D 62/10; H10D 62/60; H10D 62/834

(52) U.S. Cl. CPC H10D 30/66; H10D 30/0291; H10D 62/124; H10D 62/60; H10D 62/834

(57) ABSTRACT

A method of fabricating a semiconductor device includes forming a well region in a substrate, in which the substrate has a junction field effect transistor region adjacent to the well region; forming a source region in the well region; performing an implantation process to form a surface doped region at a portion of the well region between the source region and the junction field effect transistor region; forming a dielectric layer along an upper surface of the surface doped region and an upper surface of the junction field effect transistor region; and forming a gate structure on the dielectric layer.

### CROSS-REFERENCE TO RELATED APPLICATION

This application claims priority to Taiwan Application Serial Number 114103641, filed Jan. 24, 2025, which is herein incorporated by reference in its entirety.

### BACKGROUND

SiC (silicon carbide) performs well under extreme conditions such as high power, high frequency, and high temperature. Its main advantages over Si (silicon) in the semiconductor field include: 1. High energy band width: SiC has a larger energy band width (2.3-3.26 eV), enabling it to operate at higher voltages and higher temperatures; 2. High thermal conductivity: The thermal conductivity of SiC is about 3 times that of Si, which can effectively dissipate heat and is suitable for high power density applications; 3. High operating temperature: SiC can operate at higher temperatures (up to 600° C. or more), suitable for extreme conditions; 4. Higher switching efficiency: SiC has a faster switching speed, which can achieve higher efficiency and lower loss in high-frequency switching applications; 5. High voltage resistance: SiC can withstand higher voltages and is suitable for high voltage and high power applications such as electric vehicles and power electronic equipment.

However, SiC (silicon carbide) generally has a high defect density, mainly due to its crystal structure and growth process challenges. Common defects include dislocations, stacking faults and vacancies. These defects affect the electronic performance and reliability of SiC, resulting in higher leakage current, poor switching characteristics, and lower device reliability, especially in high-temperature and high-efficiency applications.

Therefore, there is a need for a credible apparatus and fabrication method for a semiconductor device.

### SUMMARY

The disclosure provides a method of fabricating a semiconductor device that includes forming a well region in a substrate, in which the substrate has a junction field effect transistor region adjacent to the well region; forming a source region in the well region; performing an implantation process to form a surface doped region at a portion of the well region between the source region and the junction field effect transistor region; forming a dielectric layer along an upper surface of the surface doped region and an upper surface of the junction field effect transistor region; and forming a gate structure on the dielectric layer.

In some embodiments, in which a doping species for performing the implantation process is silicon (Si).

In some embodiments, in which a doping species for performing the implantation process is germanium (Ge), boron (B), or gallium (Ga).

In some embodiments, in which the dielectric layer extends to an upper surface of the source region.

In some embodiments, in which a thickness of the surface doped region is less than a thickness of the source region.

The disclosure provides a semiconductor device that includes a substrate having a junction field effect transistor region; a well region located in the substrate and adjacent to the region; a source region located in the well region; a surface doped region located in the well region and between the junction field effect transistor region and the source region; a dielectric layer along an upper surface of the surface doped region and an upper surface of the junction field effect transistor region; and a gate structure located on the dielectric layer.

In some embodiments, in which the surface doped region has a higher silicon (Si) atomic proportion than the substrate, the well region or the source region.

In some embodiments, in which a higher germanium (Ge), boron (B), or gallium (Ga) atomic proportion than the substrate, the well region or the source region.

In some embodiments, in which the dielectric layer extends to an upper surface of the source region.

In some embodiments, in which a thickness of the surface doped region is less than a thickness of the source region.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1 to 7 are cross-sectional views of different steps of a method of fabricating a semiconductor device, in accordance with some embodiments of the present disclosure.

### DETAILED DESCRIPTION

Various example embodiments will be described more fully hereinafter with reference to the accompanying drawings, in which some example embodiments are shown. The present disclosure may, however, be embodied in many different forms and should not be construed as limited to the example embodiments set forth herein. Rather, these example embodiments are provided so that this disclosure will be thorough and complete, and will fully convey the scope of the present disclosure to those skilled in the art. It is noted that, in accordance with the standard practice in the industry, various features are not drawn to scale. In fact, the dimensions of the various features may be arbitrarily increased or reduced for clarity of discussion.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

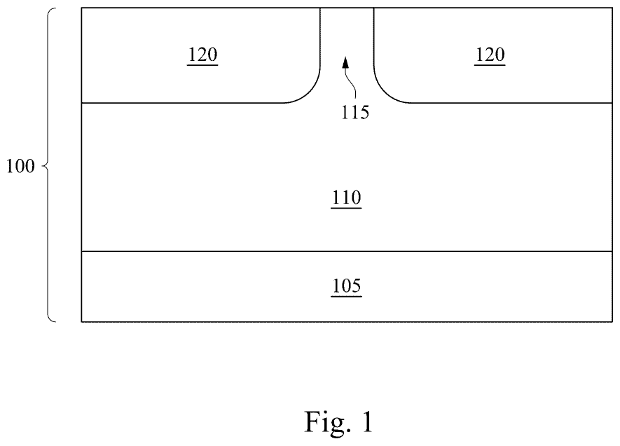

FIGS. 1 to 7 are cross-sectional views of different steps of a method of fabricating a semiconductor device, in accordance with some embodiments of the present disclosure. The method of FIGS. 1 to 7 is used to form a semiconductor device. Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

Referring to FIG. 1, a substrate 100 is shown, wherein the substrate 100 includes a substrate region 105 and a drift region 110 located above the substrate region 105. In some embodiments, the substrate 100 may be made of a semiconductor material, such as silicon carbide, silicon, the like, or a combination thereof. In some embodiments, the substrate region 105 and the drift region 110 may include a first type dopant. For example, the substrate region 105 and the drift region 110 may include N-type dopants, such as nitrogen, arsenic, and phosphorus. In some embodiments, the substrate region 105 is a heavily doped region, and the drift region 110 is a lightly doped region. For example, the dopant concentration of the first type dopant in the substrate region 105 is higher than the dopant concentration of the first type dopant in the drift region 110.

Next, a well region 120 is formed in the drift region 110. First, the well region 120 is formed on the drift region 110. In some embodiments, a first patterned photoresist layer may be formed on the drift region 110, wherein the first patterned photoresist layer has an opening. Then, an ion implantation process may be performed on the drift region 110 through the opening of the first patterned photoresist layer to implant ions into the drift region 110 to form the well region 120. The position of the well region 120 is defined by the opening of the first patterned photoresist layer. Next, the first patterned photoresist layer is removed.

In some embodiments, the well region 120 is located on the upper surfaces of the left and right sides of the drift region 110, and does not include the middle upper surface of the drift region 110. In some embodiments, the well region 120 may include a second type dopant different from the first type dopant. For example, the well region 120 may include P-type dopants, such as boron, aluminum, and gallium. In some embodiments, a portion of the drift region 110 extends between the well regions 120, and the portion may be referred to as a JFET region 115 (junction field effect transistor region).

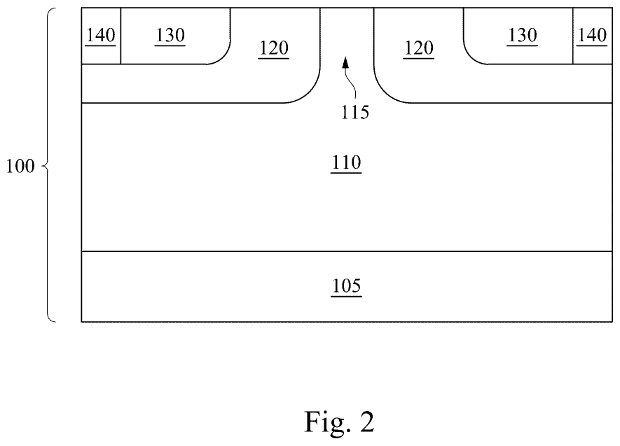

Referring to FIG. 2, a first doped region 130 and a second doped region 140 are formed. For example, a second patterned photoresist layer may be formed on a portion of the well region 120 and the drift region 110, and an ion implantation process may be performed to implant ions into the well region 120 to form the first doped region 130. The position of the first doped region 130 is defined by the second patterned photoresist layer. Next, the second patterned photoresist layer is removed. In some embodiments, the first doped region 130 is located on the upper surface of the left and right sides of the well region 120.

In some embodiments, the first doped region 130 may include a first type dopant. In some embodiments, the first doped region 130 may include N-type dopants, such as nitrogen, arsenic, or phosphorus. In some embodiments, the first doped region 130 may also be referred to as a source region or a drain region.

Next, a second doped region 140 is formed in the well region 120. In some embodiments, a third patterned photoresist layer may be formed on a portion of the first doped region 130, the well region 120, and the drift region 110, and an ion implantation process may be performed to implant ions into the well region 120 to form the second doped region 140. In some embodiments, the second doping region 140 may include second type dopants. In some embodiments, the second doped region 140 may include a P-type dopant, such as boron, aluminum, or gallium. In some embodiments, the second doped region 140 may include a higher concentration of the second type dopant than the well region 120. In some embodiments, the second doped region 140 is located in the left and right sides of the first doping region 130. The position of the second doped region 140 is defined by the third patterned photoresist layer. Next, the third patterned photoresist layer is removed.

As discussed above, in this embodiment, the first doping region 130 is formed first, and then the second doping region 140 is formed. However, in other embodiments, the second doping region 140 may be formed first, and then the first doping region 130 may be formed.

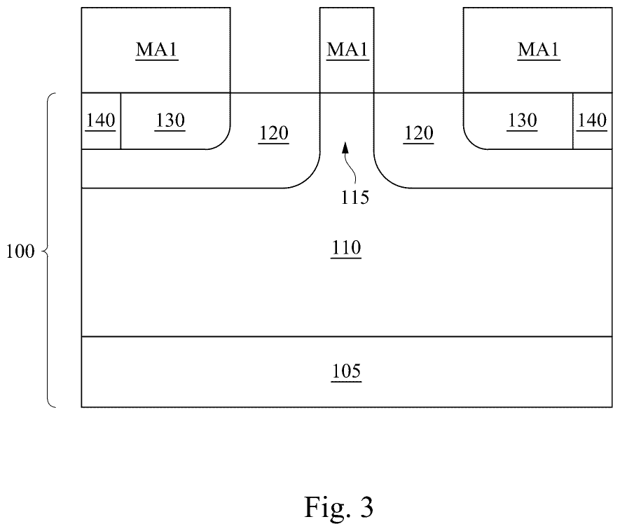

Referring to FIG. 3, a mask layer MA1 is formed to expose the well region 120. Specifically, a mask layer MA1 may be formed on the first doping region 130, the second doping region 140, and the drift region 110. In more detail, the mask layer MA1 exposes a portion of the well region 120 between the first doped region 130 and the JFET region 115. In some embodiments, the mask layer MA1 exposes the upper surface of the well region 120. In some embodiments, the mask layer MA1 may be a photoresist layer. In other embodiments, the mask layer MA1 may be a hard mask formed of a dielectric material, such as silicon nitride, silicon oxide, the like, or a combination thereof.

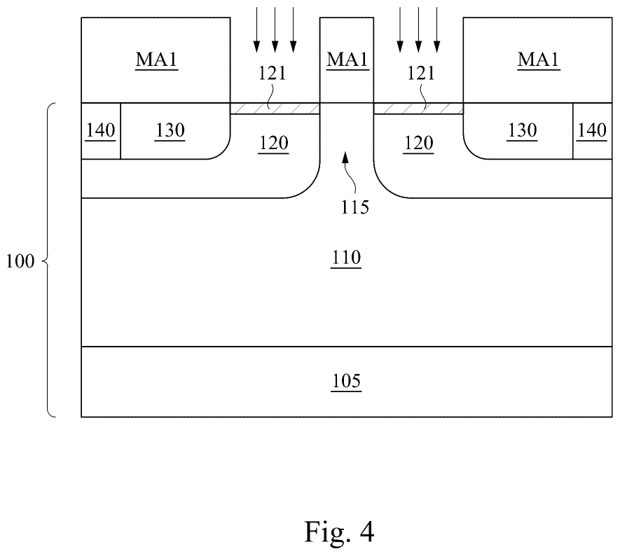

Referring to FIG. 4, an implantation process is performed on the exposed well region 120. Specifically, with the mask layer MA1 as a mask, doping species may be implanted into the exposed upper surface of the well region 120. In more detail, the implantation process implants doping species into the upper surface of the well region 120. In some embodiments, the mask layer MA1 is configured to block dopant species from being implanted into the first doping region 130, the second doping region 140, and the JFET region 115. In some embodiments, the implantation process forms a surface doped region 121 on the exposed surface of the well region 120. The surface doped region 121 may be used as a channel region in the subsequent structures, so the surface doped region 121 may also be referred to as a channel region.

In some embodiments, the doping species implanted into the upper surface of the well region 120 is a doping species that can reduce the defect density in the region to achieve improved mobility. In some embodiments, the doping species implanted into the upper surface of the well region 120 may include silicon (Si) ions, germanium (Ge), boron (B), or gallium (Ga) ions. In some embodiments, the surface doped region 121 is located on the upper surface of the well region 120, and has a vertical thickness smaller than a vertical thickness of the first doped region 130 or the second doped region 140. In some embodiments, the upper surface of the surface doped region 121 is substantially leveled with the upper surfaces of the JFET region 115, the first doped region 130, and the second doped region 140.

In an embodiment where the doping species of the surface doping region 121 is silicon (Si) ions, the material of the surface doping region 121 can be silicon carbide with a high concentration of silicon. That is, the surface doped region 121 has a higher silicon atomic proportion than other parts of the substrate 100, such as the substrate region 105, the drift region 110, the well region 120, the first doped region 130, and the second doped region 140. In other words, the surface doped region 121 has a lower carbon atomic proportion than other parts of the substrate 100, such as the substrate region 105, the drift region 110, the well region 120, the first doped region 130, and the second doped region 140. In some embodiments, since the surface doped region 121 is formed on the upper surface of the well region 120, the surface doped region 121 also has the same second type dopant as that of the well region 120, such as P-type dopant.

In the embodiment where the doping species of the surface doping region 121 is germanium (Ge), boron (B) or gallium (Ga) ions, the material of the surface doping region 121 may include silicon germanium carbide (SiGeC), silicon carbide boron (SiC: B) or silicon carbide gallium (SiC: Ga). That is, the surface doped region 121 has a higher germanium, boron or gallium atomic proportion compared to other parts of the substrate 100, such as the substrate region 105, the drift region 110, the well region 120, the first doped region 130 and the second doped region 140. In some embodiments, other portions of the substrate 100, such as the substrate region 105, the drift region 110, the well region 120, the first doping region 130, and the second doping region 140, do not have germanium, boron, or gallium, or have very low concentrations of germanium, boron or gallium. In some embodiments, since the surface doped region 121 is formed on the upper surface of the well region 120, the surface doped region 121 also has the same second type dopant as that of the well region 120, such as P-type dopant.

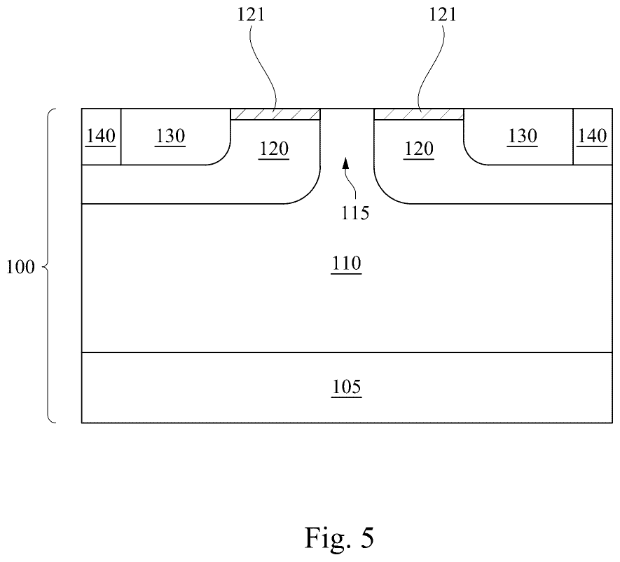

Referring to FIG. 5, the mask layer MA1 is removed. Specifically, the mask layer MA1 may be removed to expose the upper surfaces of the JFET region 115, the surface doped region 121, the first doped region 130, and the second doped region 140 in the drift region 110.

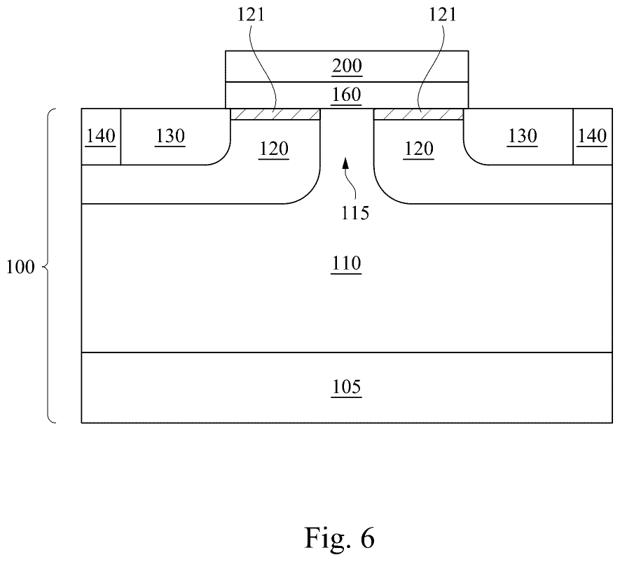

Referring to FIG. 6, a dielectric layer 160 and a gate structure 200 may be formed on the exposed surfaces of the surface doped region 121 and the drift region 110. First, a dielectric layer 160 may be deposited on the substrate 100. Next, the gate structure 200 is deposited on the dielectric layer 160. Finally, the gate dielectric layer 160 and the gate structure 200 are patterned.

In some embodiments, the dielectric layer 160 and the gate structure 200 have the same width. In some embodiments, the dielectric layer 160 covers the upper surfaces of the JFET region 115, the surface doped region 121, and the drift region 110. In some embodiments, the dielectric layer 160 also covers a portion of the upper surface of the first doped region 130. In some embodiments, the dielectric layer 160 includes a dielectric material, such as silicon oxide, silicon nitride, the like, or a combination thereof. In some embodiments, the dielectric layer 160 may be used as a gate dielectric layer and configured to electrically isolate the gate from other conductive materials, such as the drift region 110, the surface doped region 121 and/or or the first doped region 130. In some embodiments, the vertical thickness of the dielectric layer 160 is greater than the vertical thickness of the surface doped region 121. In some embodiments, the gate structure 200 may be made of a conductive material, such as polysilicon, metal, or other suitable conductive materials.

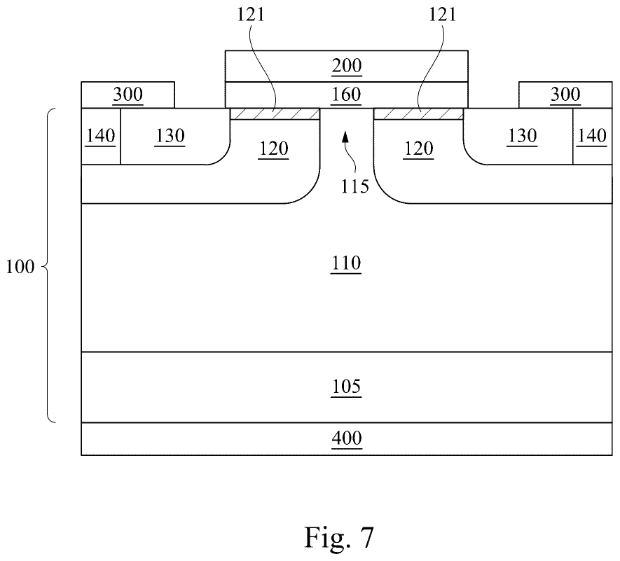

Referring to FIG. 7, a source electrode 300 is formed on a portion of the first doping region 130 and the second doping region 140, and a drain electrode 400 is formed under the substrate region 105 below the drift region 110.

In some embodiments, the source electrode 300 can be formed by forming a fifth patterned photoresist layer and depositing it. The position of the source electrode 300 is defined by the fifth patterned photoresist layer. Next, the fifth patterned photoresist layer is removed. In some embodiments, the source electrode 300 covers an upper surface of the second doping region 140 and a portion of an upper surface of the first doping region 130.

Next, the drain electrode 400 may be formed by vertically flipping the drift region 110 and depositing it on the back side of the substrate region 105 below the drift region 110. After the drain electrode 400 is formed, it can be vertically flipped back to its original position. The source electrode 300 and the drain electrode 400 may be made of a conductive material, such as metal.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of fabricating a semiconductor device, comprising:
forming a well region in a substrate, wherein the substrate has a junction field effect transistor region adjacent to the well region;
forming a source region in the well region;
performing an implantation process to form a surface doped region at a portion of the well region between the source region and the junction field effect transistor region;
forming a dielectric layer along an upper surface of the surface doped region and an upper surface of the junction field effect transistor region; and
forming a gate structure on the dielectric layer.

2. The method of claim 1, wherein a doping species for performing the implantation process is silicon (Si).

3. The method of claim 1, wherein a doping species for performing the implantation process is germanium (Ge), boron (B), or gallium (Ga).

4. The method of claim 1, wherein the dielectric layer extends to an upper surface of the source region.

5. The method of claim 1, wherein a thickness of the surface doped region is less than a thickness of the source region.

6. A semiconductor device, comprising:
a substrate having a junction field effect transistor region;
a well region located in the substrate and adjacent to the junction field effect transistor region;
a source region located in the well region;
a surface doped region located in the well region and between the junction field effect transistor region and the source region;
a dielectric layer along an upper surface of the surface doped region and an upper surface of the junction field effect transistor region; and
a gate structure located on the dielectric layer.

7. The semiconductor device of claim 6, wherein the surface doped region has a higher silicon (Si) atomic proportion than the substrate, the well region or the source region.

8. The semiconductor device of claim 6, wherein the surface doped region has a higher germanium (Ge), boron (B), or gallium (Ga) atomic proportion than the substrate, the well region or the source region.

9. The semiconductor device of claim 6, wherein the dielectric layer extends to an upper surface of the source region.

10. The semiconductor device of claim 6, wherein a thickness of the surface doped region is less than a thickness of the source region.
